(19) United States
(12) Patent Application Publication
(10) Pub. No.: US 2025/0210345 A1
(43) Pub. Date: Jun. 26, 2025

(54) PROCESSING METHOD, METHOD OF MANUFACTURING SEMICONDUCTOR DEVICE, PROCESSING APPARATUS, AND RECORDING MEDIUM

(71) Applicant: KOKUSAI ELECTRIC CORPORATION, Tokyo (JP)

(72) Inventor: Kimihiko Nakatani, Toyama-shi (JP)

(73) Assignee: KOKUSAI ELECTRIC CORPORATION, Tokyo (JP)

(21) Appl. No.: 18/918,302

(22) Filed: Oct. 17, 2024

(30) Foreign Application Priority Data
Dec. 25, 2023 (JP) 2023-217652

(51) Int. Cl. H01L 21/02; C23C 16/455

(52) U.S. Cl. CPC H01L 21/0228; C23C 16/45536; H01L 21/02274

(57) ABSTRACT

There is provided a technique that includes: forming a film in a recess on a surface of a substrate by performing a cycle n times (where n is an integer of 1 or 2 or more), the cycle including: (a) exposing the substrate to an altering agent excited into a plasma state; (b) exposing the substrate after (a) to an oxygen-containing substance; (c) exposing the substrate after (b) to a modifying agent; and (d) exposing the substrate after (c) to a film-forming agent.

### CROSS-REFERENCE TO RELATED APPLICATION

This application is based upon and claims the benefit of priority from Japanese Patent Application No. 2023-217652, filed on Dec. 25, 2023, the entire contents of which are incorporated herein by reference.

### TECHNICAL FIELD

The present disclosure relates to a processing method, a method of manufacturing a semiconductor device, a processing apparatus, and a recording medium.

### BACKGROUND OF THE INVENTION

In the related art, as a process of manufacturing a semiconductor device, a process of forming a film in a recess such as a trench or a hole formed on a surface of a substrate is performed.

### SUMMARY OF THE INVENTION

Some embodiments of the present disclosure provide a technique capable of improving properties of a film formed in a recess.

According to some embodiments of the present disclosure, there is provided a technique that includes: forming a film in a recess on a surface of a substrate by performing a cycle n times (where n is an integer of 1 or 2 or more), the cycle including: (a) exposing the substrate to an altering agent excited into a plasma state; (b) exposing the substrate after (a) to an oxygen-containing substance; (c) exposing the substrate after (b) to a modifying agent; and (d) exposing the substrate after (c) to a film-forming agent.

### BRIEF DESCRIPTION OF THE DRAWINGS

The accompanying drawings, which are incorporated in and constitute a part of the specification, illustrate embodiments of the present disclosure.

FIG. 1 is a schematic configuration diagram of a vertical process furnace of a processing apparatus suitably used in some embodiments of the present disclosure, in which a portion of the process furnace is illustrated in a vertical cross-sectional view.

FIG. 2 is a schematic configuration diagram of a vertical process furnace of a processing apparatus suitably used in some embodiments of the present disclosure, in which a portion of the process furnace is illustrated in a cross-sectional view taken along line A-A in FIG. 1.

FIG. 3 is a schematic configuration diagram of a controller of the processing apparatus suitably used in some embodiments of the present disclosure, in which a control system of the controller is illustrated in a block diagram.

FIG. 4A is a partial cross-sectional enlarged view showing a surface of a substrate according to some embodiments of the present disclosure, which includes a recess whose surface is constituted by a base film. FIG. 4B is a partial cross-sectional enlarged view showing a surface of a substrate according to some embodiments of the present disclosure after being exposed to an altering agent excited into a plasma state from a state of FIG. 4A. FIG. 4C is a partial cross-sectional enlarged view showing a surface of a substrate according to some embodiments of the present disclosure after being exposed to an oxygen-containing substance from a state of FIG. 4B. FIG. 4D is a partial cross-sectional enlarged view showing a surface of a substrate according to some embodiments of the present disclosure after being exposed to a modifying agent from a state of FIG. 4C. FIG. 4E is a partial cross-sectional enlarged view showing a surface of a substrate according to some embodiments of the present disclosure after being exposed to a film-forming agent from a state of FIG. 4D.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, sequences, systems, and components are not described above in detail so as not to obscure aspects of the various embodiments.

### Embodiments of the Present Disclosure

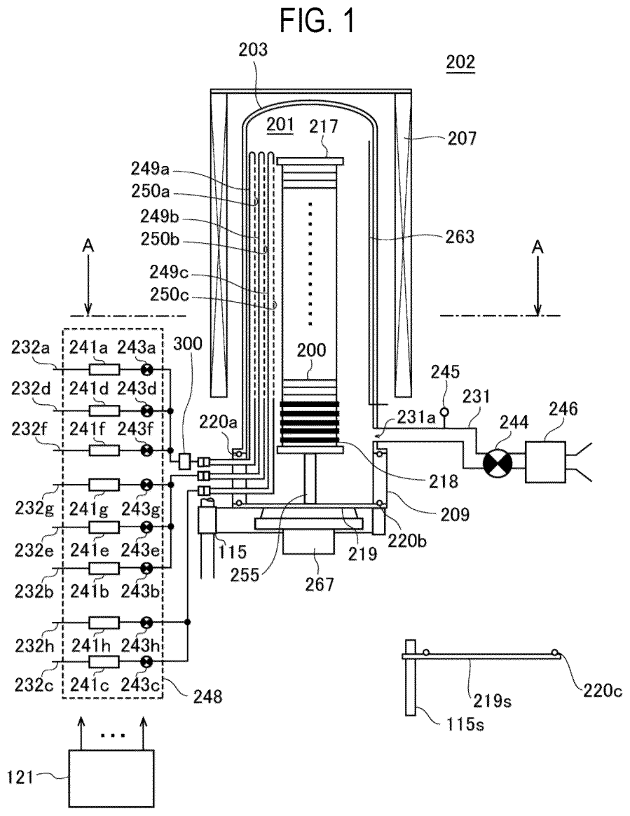

Hereinafter, some embodiments of the present disclosure will be described mainly with reference to FIGS. 1 to 3 and 4A to 4E. Drawings used in the following description are schematic, and dimensional relationships, ratios, and the like among various components shown in the drawings may not match actual ones. Further, dimensional relationship, ratios, and the like of various components among a plurality of drawings may not match one another.

### (1) Configuration of Processing Apparatus

As shown in FIG. 1, a process furnace 202 of a processing apparatus includes a heater 207 as a temperature regulator (a heating part). The heater 207 is formed in a cylindrical shape and is vertically installed by being supported by a holding plate. The heater 207 functions as an activator (an exciter) configured to activate (excite) a gas with heat.

A reaction tube 203 is disposed inside the heater 207 to be concentric with the heater 207. The reaction tube 203 is made of, for example, heat resistant material such as quartz (SiO₂) or silicon carbide (SiC), and is formed in a cylindrical shape with its upper end closed and its lower end opened. A manifold 209 is disposed to be concentric with the reaction tube 203 under the reaction tube 203. The manifold 209 is made of, for example, metal material such as stainless steel (SUS), and is formed in a cylindrical shape with both of its upper and lower ends opened. The upper end of the manifold 209 engages with the lower end of the reaction tube 203 to support the reaction tube 203. An O-ring 220a serving as a seal is provided between the manifold 209 and the reaction tube 203. Similar to the heater 207, the reaction tube 203 is vertically installed. A process container (reaction container) mainly includes the reaction tube 203 and the manifold 209. A process chamber 201 is formed in a hollow cylindrical area of the process container. The process chamber 201 is configured to be capable of accommodating wafers 200 as substrates. The wafers 200 are processed in the process chamber 201.

Nozzles 249a to 249c as first to third suppliers are respectively installed in the process chamber 201 to penetrate through a sidewall of the manifold 209. The nozzles 249a to 249c are also referred to as first to third nozzles, respectively. The nozzles 249a to 249c are made of, for example, heat resistant material such as quartz or SiC. Gas supply pipes 232a to 232c are connected to the nozzles 249a to 249c, respectively. The nozzles 249a to 249c are different nozzles, and each of the nozzles 249a and 249c is installed adjacent to the nozzle 249b.

Mass flow controllers (MFCs) 241a to 241c, which are flow rate controllers (flow rate control parts), and valves 243a to 243c, which are opening/closing valves, are installed at the gas supply pipes 232a to 232c, respectively, sequentially from the upstream side of a gas flow. Gas supply pipes 232d and 232f are respectively connected to the gas supply pipe 232a at the downstream side of the valves 243a. Gas supply pipes 232e and 232g are respectively connected to the gas supply pipe 232b at the downstream side of the valves 243b. A gas supply pipe 232h is connected to the gas supply pipe 232c at the downstream side of the valves 243c. MFCs 241d to 241h and valves 243d to 243h are installed at the gas supply pipes 232d to 232h, respectively, sequentially from the upstream side of a gas flow. The gas supply pipes 232a to 232h are made of, for example, metal material such as SUS.

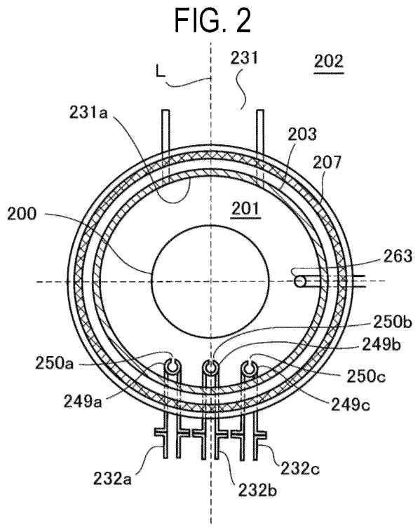

As shown in FIG. 2, the nozzles 249a to 249c are respectively installed in an annular space (in a plane view) between an inner wall of the reaction tube 203 and the wafers 200 to extend upward from a lower side to an upper side of the inner wall of the reaction tube 203, that is, along an arrangement direction of the wafers 200. Specifically, the nozzles 249a to 249c are respectively installed in a region horizontally surrounding a wafer arrangement region in which the wafers 200 are arranged at a lateral side of the wafer arrangement region, along the wafer arrangement region. In the plane view, the nozzle 249b is disposed to face an exhaust port 231a to be described below in a straight line with centers of the wafers 200, which are loaded into the process chamber 201, interposed therebetween. The nozzles 249a and 249c are arranged to sandwich a straight line L passing through the nozzle 249b and the center of the exhaust port 231a from both sides along the inner wall of the reaction tube 203 (an outer periphery of the wafers 200). The straight line L is also a straight line passing through the nozzle 249b and the centers of the wafers 200. That is, the nozzle 249c may be installed at the opposite side of the nozzle 249a with the straight line L interposed therebetween. The nozzles 249a and 249c are arranged in line symmetry with the straight line L as an axis of symmetry. Gas supply holes 250a to 250c configured to supply a gas are formed on the side surfaces of the nozzles 249a to 249c, respectively. Each of the gas supply holes 250a to 250c is opened to oppose (face) the exhaust port 231a in the plane view, which enables a gas to be supplied toward the wafers 200. A plurality of gas supply holes 250a to 250c are formed from the lower side to the upper side of the reaction tube 203.

An altering agent is supplied from the gas supply pipe 232a into the process chamber 201 via the MFC 241a, the valve 243a, and the nozzle 249a.

An oxygen-containing substance is supplied from the gas supply pipe 232b into the process chamber 201 via the MFC 241b, the valve 243b, and the nozzle 249b.

A modifying agent is supplied from the gas supply pipe 232c into the process chamber 201 via the MFC 241c, the valve 243c, and the nozzle 249c.

A reactant serving as a film-forming agent is supplied from the gas supply pipe 232d into the process chamber 201 via the MFC 241d, the valve 243d, the gas supply pipe 232a, and the nozzle 249a.

A precursor serving as a film-forming agent is supplied from the gas supply pipe 232e into the process chamber 201 via the MFC 241e, the valve 243e, the gas supply pipe 232b, and the nozzle 249b.

An inert gas is supplied from the gas supply pipes 232f to 232h into the process chamber 201 via the MFCs 241f to 241h, the valves 243f to 243h, the gas supply pipes 232a to 232c, and the nozzles 249a to 249c, respectively. The inert gases act as a purge gas, a carrier gas, a dilution gas, and the like.

A remote plasma unit (RPU) 300 as a plasma exciter (a plasma generator) configured to excite a gas such as an altering agent into a plasma state is installed at the gas supply pipe 232a at the downstream side of a connection portion between the gas supply pipe 232a and the gas supply pipe 232f. Exciting a gas into a plasma state is also simply referred to as plasma-exciting a gas. By applying a radio frequency (RF) power, the RPU 300 may plasma-excite a gas, i.e., excite a gas into a plasma state inside the RPU 300. As a plasma generation method, a capacitively coupled plasma (abbreviation: CCP) method or an inductively coupled plasma (abbreviation: ICP) method may be used. The RPU 300 is configured to be capable of plasma-exciting an altering agent, a reactant, and an inert gas supplied from the gas supply pipes 232a, 232d, and 232f and supplying the same to the process chamber 201. The RPU 300 is also simply referred to as an exciter.

An altering agent supply system (a first exposure system) mainly includes the gas supply pipe 232a, the MFC 241a, and the valve 243a. An oxygen-containing substance supply system (a second exposure system) mainly includes the gas supply pipe 232b, the MFC 241b, and the valve 243b. A modifying agent supply system (a third exposure system) mainly includes the gas supply pipe 232c, the MFC 241c, and the valve 243c. A reactant supply system mainly includes the gas supply pipe 232d, the MFC 241d, and the valve 243d. A precursor supply system mainly includes the gas supply pipe 232e, the MFC 241e, and the valve 243e. An inert gas supply system mainly includes the gas supply pipes 232f to 232h, the MFCs 241f to 241h, and the valves 243f to 243h. Each or the entirety of the precursor supply system and the reactant supply system is also referred to as a film-forming agent supply system (a fourth exposure system). The RPU 300 may be included in the altering agent supply system.

One or the entirety of the above-described various supply systems may be constituted as an integrated supply system 248 in which the valves 243a to 243h, the MFCs 241a to 241h, and so on are integrated. The integrated supply system 248 is connected to each of the gas supply pipes 232a to 232h, and is configured such that an operation of supplying various materials (various gases) into the gas supply pipes 232a to 232h (that is, an opening/closing operation of the valves 243a to 243h, a flow rate regulation operation by the MFCs 241a to 241h, and the like) are controlled by a controller 121 to be described below. The integrated supply system 248 is constituted as an integral type or division type integrated unit, and may be attached to or detached from the gas supply pipes 232a to 232h and the like on an integrated unit basis, such that maintenance, replacement, extension, and the like of the integrated supply system 248 may be performed on an integrated unit basis.

The exhaust port 231a configured to exhaust an internal atmosphere of the process chamber 201 is installed at the lower side of the sidewall of the reaction tube 203. As shown in FIG. 2, the exhaust port 231a is installed at a position opposing (facing) the nozzles 249a to 249c (the gas supply holes 250a to 250c) with the wafers 200 interposed therebetween in the plane view. The exhaust port 231a may be installed to extend from the lower side to the upper side of the sidewall of the reaction tube 203, that is, along the wafer arrangement region. An exhaust pipe 231 is connected to the exhaust port 231a. A vacuum pump 246 as a vacuum exhauster is connected to the exhaust pipe 231 via a pressure sensor 245, which is a pressure detector (pressure detection part) configured to detect an internal pressure of the process chamber 201, and an auto pressure controller (APC) valve 244, which is a pressure regulator (pressure regulation part). The APC valve 244 is configured to be capable of performing or stopping vacuum exhausting operation of an inside of the process chamber 201 by being opened/closed while the vacuum pump 246 is actuated, and is also configured to be capable of regulating the internal pressure of the process chamber 201 by adjusting a degree of valve opening based on pressure information detected by the pressure sensor 245 while the vacuum pump 246 is actuated. An exhaust system mainly includes the exhaust pipe 231, the APC valve 244, and the pressure sensor 245. The exhaust system may include the vacuum pump 246.

A seal cap 219 as a furnace opening lid configured to be capable of airtightly closing a lower end opening of the manifold 209 is installed below the manifold 209. The seal cap 219 is made of, for example, metal material such as SUS, and is formed in a disc shape. An O-ring 220b as a seal, which comes into contact with the lower end of the manifold 209, is installed on an upper surface of the seal cap 219. A rotator 267 configured to rotate a boat 217 to be described below is installed below the seal cap 219. A rotary shaft 255 of the rotator 267 is connected to the boat 217 through the seal cap 219. The rotator 267 is configured to rotate the wafers 200 by rotating the boat 217. The seal cap 219 is configured to be vertically moved up or down by a boat elevator 115 which is an elevator installed outside the reaction tube 203. The boat elevator 115 is constituted as a transfer apparatus (transfer mechanism) which loads/unloads (transfers) the wafers 200 into/out of the process chamber 201 by moving the seal cap 219 up or down.

Below the manifold 209, a shutter 219s is installed as a furnace opening lid configured to be capable of airtightly closing the lower end opening of the manifold 209 while the seal cap 219 is lowered and the boat 217 is unloaded from the process chamber 201. The shutter 219s is made of, for example, metal material such as SUS, and is formed in a disc shape. An O-ring 220c as a seal, which comes into contact with the lower end of the manifold 209, is installed on an upper surface of the shutter 219s. The opening/closing operation (such as elevation operation, rotation operation, or the like) of the shutter 219s is controlled by a shutter opening/closing mechanism 115s.

The boat 217 serving as a substrate support is configured to support a plurality of wafers 200, for example, 25 to 200 wafers, in such a state that the wafers 200 are arranged in a horizontal posture and in multiple stages along a vertical direction with the centers of the wafers 200 aligned with one another. That is, the boat 217 is configured to arrange the wafers 200 to be spaced apart from each other. The boat 217 is made of, for example, heat resistant material such as quartz or SiC. Heat insulating plates 218 made of, for example, heat resistant material such as quartz or SiC are installed in multiple stages at the bottom of the boat 217.

A temperature sensor 263 serving as a temperature detector is installed in the reaction tube 203. Based on temperature information detected by the temperature sensor 263, a state of supplying electric power to the heater 207 is regulated such that a temperature distribution in the process chamber 201 becomes a desired temperature distribution. The temperature sensor 263 is installed along the inner wall of the reaction tube 203.

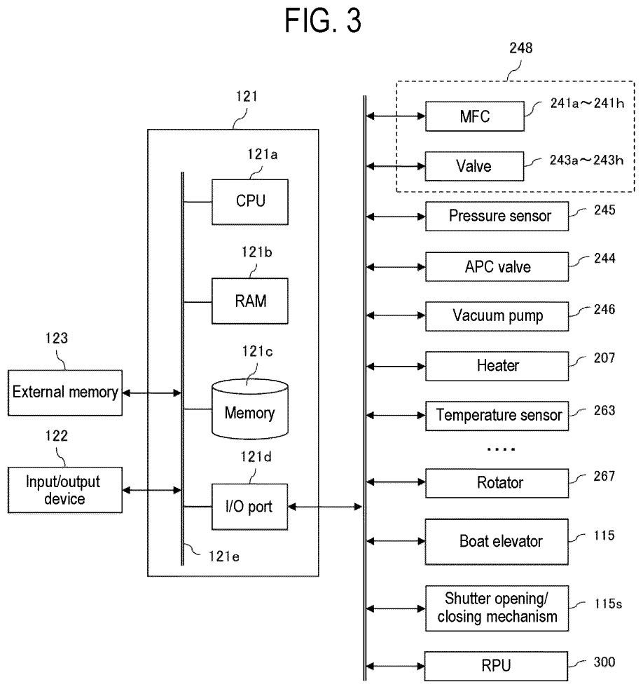

As shown in FIG. 3, the controller 121 as a control part (control means or unit) is constituted as a computer including a central processing unit (CPU) 121a, a random access memory (RAM) 121b, a memory 121c and an I/O port 121d. The RAM 121b, the memory 121c, and the I/O port 121d are configured to be capable of exchanging data with the CPU 121a via an internal bus 121e. An input/output device 122 constituted as, for example, a touch panel or the like is connected to the controller 121. Further, an external memory 123 may be connected to the controller 121. The processing apparatus may be configured to include one controller or a plurality of controllers. That is, a control to perform a processing sequence to be described below may be performed by using one controller or a plurality of controllers. Further, the plurality of controllers may be constituted as a control system in which the controllers are connected to each other via a wired or wireless communication network, and the control to perform the processing sequence to be described below may be performed by the entire control system. When the term “controller” is used herein, it may indicate a case of including a controller, a case of including a plurality of controllers, or a case of including a control system constituted by a plurality of controllers.

The memory 121c includes, for example, a flash memory, a hard disk drive (HDD), a solid state drive (SSD), or the like. A control program that controls operations of a processing apparatus, a process recipe in which sequences and conditions of substrate processing to be described below are written, and the like are readably recorded and stored in the memory 121c. The process recipe functions as a program that causes, by the controller 121, the processing apparatus to perform each sequence in the substrate processing (film-forming processing) to be described below to obtain an expected result. Hereinafter, the process recipe and the control program may be generally and simply referred to as a “program.” Further, the process recipe may be simply referred to as a “recipe.” When the term “program” is used herein, it may indicate a case of including the recipe, a case of including the control program, or a case of including both the recipe and the control program. The RAM 121b is constituted as a memory area (work area) in which programs or data read by the CPU 121a are temporarily stored.

The I/O port 121d is connected to the MFCs 241a to 241h, the valves 243a to 243h, the pressure sensor 245, the APC valve 244, the vacuum pump 246, the temperature sensor 263, the heater 207, the rotator 267, the boat elevator 115, the shutter opening/closing mechanism 115s, the RPU 300, and the like.

The CPU 121a is configured to be capable of reading and executing the control program from the memory 121c. The CPU 121a is also configured to be capable of reading the recipe from the memory 121c according to an input of an operation command from the input/output device 122, or the like. The CPU 121a is configured to be capable of controlling the flow rate regulating operation of various kinds of materials (gases) by the MFCs 241a to 241h, the opening/closing operation of the valves 243a to 243h, the opening/closing operation of the APC valve 244, the pressure regulating operation performed by the APC valve 244 based on the pressure sensor 245, the actuating and stopping operation of the vacuum pump 246, the temperature regulating operation performed by the heater 207 based on the temperature sensor 263, the operation of rotating the boat 217 and adjusting the rotation speed of the boat 217 with the rotator 267, the operation of moving the boat 217 up or down by the boat elevator 115, the opening/closing operation of the shutter 219s by the shutter opening/closing mechanism 115s, the plasma excitation operation for the gas by the RPU 300, and so on, according to contents of the read recipe.

The controller 121 may be constituted by installing, in the computer, the above-described program stored in the external memory 123. Examples of the external memory 123 may include a magnetic disc such as a HDD, an optical disc such as a CD, a magneto-optical disc such as a MO, a semiconductor memory such as a USB memory or a SSD, and the like. The memory 121c or the external memory 123 is constituted as a computer-readable recording medium. Hereinafter, the memory 121c and the external memory 123 may be generally and simply referred to as a “recording medium.” When the term “recording medium” is used herein, it may indicate a case of including the memory 121c, a case of including the external memory 123, or a case of including both the memory 121c and the external memory 123. Furthermore, the program may be provided to the computer by using communication means or unit such as the Internet or a dedicated line, instead of using the external memory 123.

### (2) Processing Process

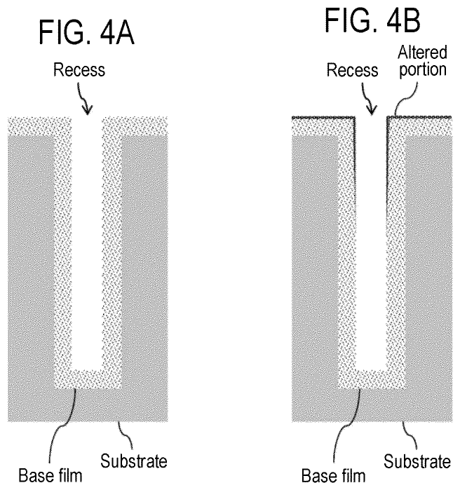

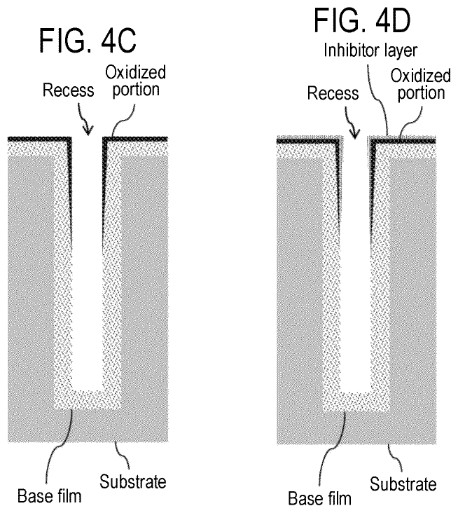

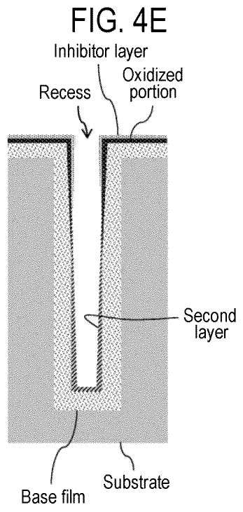

An example of a method of processing a substrate (processing method), i.e., a processing sequence to form a film on the surface of a wafer 200 as a substrate, will be described as a process (method) of manufacturing a semiconductor device by using the above-described processing apparatus mainly with reference to FIGS. 4A to 4E. In the embodiments of the present disclosure, an example will be described in which the wafer 200 is a silicon substrate (silicon wafer) with a recess such as a trench and a hole formed on the surface thereof. In the following description, an operation of each component constituting the processing apparatus is controlled by the controller 121. The processing apparatus may also be referred to as a substrate processing apparatus, a film-forming apparatus, or a film formation processing apparatus. The processing method may also be referred to as a method of processing a substrate, a method of forming a film, or a film formation processing method.

In a processing sequence according to the embodiments of the present disclosure, a film is formed in a recess on a surface of a wafer 200 by performing a cycle n times (where n is an integer of 1 or 2 or more), the cycle including:
(a) step A of exposing the wafer 200 to an altering agent excited into a plasma state;
(b) step B of exposing the wafer 200 after step A to an oxygen-containing substance;
(c) step C of exposing the wafer 200 after step B to a modifying agent; and
(d) step D of exposing the wafer 200 after step C to a film-forming agent.
   This series of processes is also called a film-forming process.

In the following example, a case will be described where the above-described cycle is performed once, i.e., n=1. Further, in the following example, a case will be described where, in step D, a sub-cycle including step D1 of exposing the wafer 200 to a precursor as a film-forming agent and step D2 of exposing the wafer 200 to a reactant as a film-forming agent D, i.e., a sub-cycle of performing step D1 and step D2 alternately (non-simultaneously), is performed a predetermined number of times (m times where m is an integer of 1 or 2 or more).

In the present disclosure, for the sake of convenience, the above-described processing sequence may be denoted as follows. The same notation may be used in the following descriptions of modifications, and the like.

[altering agent→oxygen-containing substance→modifying agent→(precursor→reactant)×m]×n

The term “wafer” used herein may refer to a wafer itself or a stacked body of a wafer and a predetermined layer or film formed on a surface of the wafer. The phrase “a surface of a wafer” used herein may refer to a surface of a wafer itself or a surface of a predetermined layer or the like formed on a wafer. The expression “a predetermined layer is formed on a surface of a wafer” used herein may mean that a predetermined layer is directly formed on a surface of a wafer itself or that a predetermined layer is formed on a layer or the like formed on a wafer. The term “substrate” used herein may be synonymous with the term “wafer.”

As used herein, terms such as “agent,” and “substance” include at least one selected from the group of a gaseous substance and a liquid substance. The liquid substance includes a mist-like substance. That is, each of the altering agent, the oxygen-containing substance, the modifying agent, and the film-forming agent may include a gaseous substance, a liquid substance such as a mist-like substance, or both.

### Wafer Charging and Boat Loading

After the boat 217 is charged with a plurality of wafers 200 (wafer charging), the shutter 219s is moved by the shutter opening/closing mechanism 115s and the lower end opening of the manifold 209 is opened (shutter opening). Thereafter, as shown in FIG. 1, the boat 217 supporting the plurality of wafers 200 is lifted by the boat elevator 115 and loaded into the process chamber 201 (boat loading). In this state, the seal cap 219 seals the lower end of the manifold 209 via the O-ring 220b. Thus, the wafers 200 are prepared inside the process chamber 201.

The wafer 200 charged to the boat 217 is provided with a recess such as a hole and a trench on the surface of the wafer 200 as shown in FIG. 4A. A surface of the recess is constituted by a base film, i.e., a silicon nitride film (SiN film) as a nitride film. In a case where a native oxide film is formed on the surface of the wafer 200, a cleaning process (DHF cleaning) may be performed by using, for example, a diluted hydrofluoric acid (DHF) solution, i.e., a hydrogen fluoride (HF) solution, on the wafer 200 before loading the boat, to remove the native oxide film formed on the surface of the wafer 200 (removal of native oxide film).

### Pressure Regulation and Temperature Regulation

After the boat loading is completed, the inside of the process chamber 201, that is, a space where the wafers 200 are placed, is vacuum-exhausted (decompression-exhausted) by the vacuum pump 246 to reach a desired pressure (state of vacuum). In this operation, the internal pressure of the process chamber 201 is measured by the pressure sensor 245, and the APC valve 244 is feedback-controlled based on the measured pressure information. Further, the wafers 200 in the process chamber 201 are heated by the heater 207 to reach a desired processing temperature. In this operation, a state of supplying electric power to the heater 207 is feedback-controlled based on the temperature information detected by the temperature sensor 263 such that a temperature distribution in the process chamber 201 becomes a desired temperature distribution. Further, the rotation of the wafers 200 by the rotator 267 is started. The exhaust of the inside of the process chamber 201 and the heating and rotation of the wafers 200 may be continuously performed at least until the processing on the wafers 200 is completed.

### Step A

Then, the wafer 200 with the recess on the surface thereof is exposed to an altering agent excited into a plasma state.

Specifically, the valve 243a is opened to allow an altering agent to flow through the gas supply pipe 232a. A flow rate of the altering agent is regulated by the MFC 241a. The altering agent is excited into a plasma state by the RPU 300, then supplied into the process chamber 201 via the nozzle 249a, and exhausted via the exhaust port 231a. At this time, the plasma-excited altering agent is supplied to the wafer 200 from a lateral side of the wafer 200 (supply of altering agent). In this way, active species (excited species) generated by plasma-exciting the altering agent are supplied to the wafer 200. At this time, the valves 243f to 243h may be opened to supply an inert gas into the process chamber 201 via each of the nozzles 249a to 249c.

By exposing the wafer 200 to the plasma-excited altering agent under a processing condition to be described below, the active species generated by plasma-exciting the altering agent may be reacted with a surface of an upper portion of the recess, and the surface of the upper portion of the recess may be selectively altered as shown in FIG. 4B. A portion of the surface of the recess altered by being exposed to the plasma-excited altering agent is also referred to as an altered portion.

In the present disclosure, the expression “active species are reacted with a surface of an upper portion of a recess” does not mean that “active species are reacted with merely a surface of an upper portion of a recess” but means that “active species are reacted with at least a surface of an upper portion of a recess.” In other words, such expression means that “a reaction between active species and a surface of an upper portion of a recess is preferentially performed over a reaction between active species and a surface of a portion other than an upper portion of a recess,” and does not exclude “a reaction between active species and a surface of a portion other than an upper portion of a recess.” Herein, the expression “a portion other than an upper portion of a recess” means “at least one selected from the group of a middle portion, a lower portion, and a bottom portion of a recess.”

Further, in the present disclosure, the expression “a surface of an upper portion of a recess is selectively altered” does not mean that “merely a surface of an upper portion of a recess is altered,” but means a relative relationship of a degree of processing on a surface. In other words, such expression means that “a surface of an upper portion of a recess is preferentially altered over a surface of a portion other than the upper portion of the recess to make a degree of alteration of the surface of the upper portion of the recess be larger than a degree of alteration of the surface of the portion other than the upper portion of the recess,” and does not exclude “alteration of the surface of the portion other than the upper portion of the recess.”

The same applies to the following description of each step, i.e., description on exposure of the wafer 200 to an oxygen-containing substance, a modifying agent, and a film-forming agent.

In this step, when the wafer 200 is exposed to an altering agent excited to a plasma state, at least a part of active species supplied to the wafer 200 may be consumed and deactivated by being reacted with the surface of the upper portion of the recess. As a result, it is possible to reduce an amount of active species supplied per unit surface area in the portion other than the upper portion of the recess, as compared to the upper portion of the recess. This makes it possible to suppress a reaction between the active species and the surface in the portion other than the upper portion of the recess, as compared to the upper portion of the recess. This effect is particularly noticeable when the altering agent is plasma-excited and supplied to the wafer 200, i.e., when the active species generated by plasma excitation of the altering agent is supplied.

As a result, in this step, for example, a composition of the material constituting the surface of the upper portion of the recess may be made to be different from a composition of the material constituting the surface of the portion other than the upper portion of the recess. Further, for example, it is possible to make the composition of the material constituting the surface of the upper portion of the recess be different from a stoichiometric composition of the material. Further, for example, it is possible to break a bond between elements that constitute the material constituting the surface of the upper portion of the recess. Further, for example, it is possible to make an oxidation resistance of the surface of the upper portion of the recess be lower than an oxidation resistance of the surface of the portion other than the upper portion of the recess.

Further, in this step, by controlling a lifetime of the active species, it is possible to adjust a region to be altered on the surface of the recess. For example, by lengthening the lifetime of the active species, it is possible to make an adjustment so that a region in the recess exposed to the active species may be expanded and an area of an altered portion formed in the recess may be increased. Further, for example, by shortening the lifetime of the active species, it is possible to make an adjustment so that the region in the recess exposed to the active species may be reduced and the area of the altered portion formed in the recess may be decreased.

The lifetime of the active species may be controlled by regulating a processing condition to be described below. For example, when the altering agent is plasma-excited and supplied, the lifetime of the active species may be controlled to be longer by lowering a processing pressure, and the lifetime of the active species may be controlled to be shorter by increasing the processing pressure.

After the surface of the upper portion of the recess is altered, the valve 243a is closed to stop the supply of the altering agent into the process chamber 201. Then, the inside of the process chamber 201 is vacuum-exhausted to remove gaseous substances and the like remaining in the process chamber 201 from the process chamber 201. At this time, the valves 243f to 243h are opened to supply an inert gas into the process chamber 201 via the nozzles 249a to 249c. The inert gas supplied from the nozzles 249a to 249c acts as a purge gas, and therefore the inside of the process chamber 201 is purged (purging).

The altering agent may be, for example, a nitrogen-containing substance such as a nitrogen (N₂) gas or an ammonia (NH₃) gas. A process of plasma-exciting the nitrogen-containing substance and supplying the same to the wafer 200 is also called a nitrogen-containing plasma process, and active species (N₂*, NH₃*, N*, etc.) generated in this process are also called nitrogen-containing active species (nitrogen-containing radicals).

Further, the altering agent may be, for example, a hydrogen-containing substance such as a hydrogen (H₂) gas or the like. A process of plasma-exciting the hydrogen-containing substance and supplying the same to the wafer 200 is also called a hydrogen-containing plasma process, and active species (H₂*, H*, etc.) generated in this process are also called hydrogen-containing active species (hydrogen-containing radicals).

Further, the altering agent may be, for example, a deuterium-containing substance such as a deuterium (D₂) gas or the like. A process of plasma-exciting the deuterium-containing substance and supplying the same to the wafer 200 is also called a deuterium-containing plasma process, and active species (D₂*, D*, etc.) generated in this process are also called deuterium-containing active species (deuterium-containing radicals).

One or more of these gases may be used as the altering agent. Further, any combination of these gases may also be used as the altering agent.

As the inert gas, a nitrogen (N₂) gas, or a rare gas such as an argon (Ar) gas, a helium (He) gas, a neon (Ne) gas or a xenon (Xe) gas may be used. One or more of these gases may be used as the inert gas. The same applies to each step to be described below.

A processing condition when the altering agent is plasma-excited and supplied in step A is exemplified as follows:

Processing temperature: room temperature (25 degrees C.) to 600 degrees C., specifically 50 to 400 degrees C.,
Processing pressure: 1 to 10,000 Pa, specifically, 50 to 1,000 Pa,
Processing time: 1 to 600 seconds, specifically, 2 to 300 seconds,
Supply flow rate of altering agent: 0.01 to 10 slm, specifically, 0.1 to 5 slm,
Supply flow rate of inert gas (for each gas supply pipe): 0 to 20 slm,
RF power: 1 to 10,000 W, specifically, 100 to 5,000 W, and
RF frequency: 13.5 MHz or 27 MHz.

In the present disclosure, notation of a numerical range such as “25 to 600 degrees C.” means that a lower limit value and an upper limit value are included in the range. Therefore, for example, “25 to 600 degrees C.” means “25 degrees C. or higher and 600 degrees C. or lower.” The same applies to other numerical ranges. In the present disclosure, the processing temperature means the temperature of the wafer 200 or the internal temperature of the process chamber 201, and the processing pressure means the internal pressure of the process chamber 201. Further, the processing time means a time during which a process is continued. Further, when 0 slm is included in the supply flow rate, 0 slm means a case where no substance (gas) is supplied. Further, the RF power means a radio frequency power applied to an electrode of the RPU 300 when the altering agent is plasma-excited, and the RF frequency means a frequency of the RF power described above. The same applies to the following description.

A processing condition when the purging is performed in step A is exemplified as follows:
Processing pressure: 1 to 30 Pa,
Processing time: 1 to 120 seconds, specifically, 1 to 60 seconds, and
Supply flow rate of inert gas (for each gas supply pipe): 0.5 to 20 slm.

The processing temperature during the purging in this step may be made to be the same as the processing temperature during the supply of the altering agent.

### Step B

After step A is completed, the wafer 200 in which the upper portion of the recess is selectively altered is exposed to an oxygen-containing substance.

Specifically, the valve 243b is opened to allow an oxygen-containing substance to flow through the gas supply pipe 232b. A flow rate of the oxygen-containing substance is adjusted by the MFC 241b. The oxygen-containing substance is supplied into the process chamber 201 via the nozzle 249b, and is exhausted via the exhaust port 231a. At this time, the oxygen-containing substrate is supplied to the wafer 200 from the lateral side of the wafer 200 (supply of oxygen-containing substance). At this time, the valves 243f to 243h may be opened to supply an inert gas into the process chamber 201 via each of the nozzles 249a to 249c.

By exposing the wafer 200 to the oxygen-containing substance under a processing condition to be described below, it is possible to selectively (preferentially) oxidize the altered portion on the surface of the upper portion of the recess as shown in FIG. 4C. A portion of the surface of the recess oxidized by being exposed to the oxygen-containing substance is also referred to as an oxidized portion.

In this step, for example, an oxygen concentration in the surface of the upper portion of the recess may be made to be different from an oxygen concentration in the surface of the portion other than the upper portion of the recess. Further, for example, a density of an OH termination on the surface of the upper portion of the recess may be made to be different from a density of an OH termination on the surface of the portion other than the upper portion of the recess.

After the altered portion on the surface of the upper portion of the recess is oxidized, the valve 243b is closed to stop the supply of the oxygen-containing substance into the process chamber 201. Then, gaseous substances and the like remaining in the process chamber 201 are removed from the process chamber 201 by the same processing sequence and processing condition as during the purging in step A (purging). The processing temperature during the purging in this step may be the same as the processing temperature during the supply of the oxygen-containing substance.

As the oxygen-containing substance, for example, at least one selected from the group of an oxygen-containing gas, an oxygen-and hydrogen-containing gas, an oxygen-and nitrogen-containing gas, and an oxygen-and carbon-containing gas may be used. As the oxygen-containing gas, for example, an oxygen (O₂) gas, an ozone (O₃) gas, O₂ gas+H₂ gas, O₂ gas+D₂ gas, O₃ gas+H₂ gas, O₃ gas+D₂ gas, a hydrogen peroxide (H₂O₂) gas, a water vapor (H₂O gas), a nitrous oxide (N₂O) gas, a nitric oxide (NO) gas, a nitrogen dioxide (NO₂) gas, a carbon dioxide (CO₂) gas, a carbon monoxide (CO) gas, and the like may be used. One or more of these gases may be used as the oxygen-containing substance. Herein, description of two gases in combination, such as “O₂ gas+H₂ gas,” means a mixed gas of an O₂ gas and a H₂ gas. When the mixed gas is supplied, two gases may be mixed (pre-mixed) in the supply pipe, and then supplied into the process chamber 201, or two gases may be separately supplied into the process chamber 201 via different supply pipes, and then mixed (post-mixed) in the process chamber 201.

A processing condition when the oxygen-containing substance is supplied in step B is exemplified as follows:
Processing temperature: room temperature (25 degrees C.) to 600 degrees C., specifically, 50 to 400 degrees C.,
Processing pressure: 1 to 105,000 Pa, specifically, 10 to 10,000 Pa,
Processing time: 1 to 10,000 seconds, specifically, 5 to 3,600 seconds, and
Supply flow rate of oxidizing agent: 0.01 to 10 slm, specifically, 0.1 to 5 slm.

In step B, the substrate after step A is performed, i.e., the wafer 200 after the upper portion of the recess is selectively altered, may be temporarily unloaded from the process chamber 201 and exposed to an atmosphere. Even in such a case, it is possible to selectively oxidize the altered portion of the surface of the upper portion of the recess. Further, in such a case, it is possible to allow the oxidation reaction that occurs at this time to proceed mildly. In such a case, the oxygen-containing substance including an oxygen-containing gas, an oxygen- and hydrogen-containing gas, an oxygen- and nitrogen-containing gas, and an oxygen- and carbon-containing gas in the atmosphere contribute to the oxidation.

A processing condition when the wafer 200 is exposed to the atmosphere in step B is exemplified as follows:
Processing temperature: room temperature (25 degrees C.),
Processing pressure: atmospheric pressure, and
Processing time: 1 to 200,000 seconds, specifically, 60 to 10,000 seconds.

### Step C

After step B is completed, the wafer 200 in which the altered portion of the upper portion of the recess is oxidized is exposed to a modifying agent.

Specifically, the valve 243c is opened to allow a modifying agent to flow through the gas supply pipe 232c. A flow rate of the modifying agent is regulated by the MFC 241c. The modifying agent is supplied into the process chamber 201 via the nozzle 249c, and is exhausted via the exhaust port 231a. At this time, the modifying agent is supplied to the wafer 200 from the lateral side of the wafer 200 (supply of modifying agent). At this time, the valves 243f to 243h may be opened to supply an inert gas into the process chamber 201 via each of the nozzles 249a to 249c.

By exposing the wafer 200 to the modifying agent under a processing condition to be described below, it is possible to selectively (preferentially) modify the oxidized portion of the surface of the upper portion of the recess as shown in FIG. 4D. Specifically, it is possible to selectively form an inhibitor layer on the surface of the upper portion of the recess by causing an inhibitor molecule, which is at least a part of a molecular structure of a molecule constituting the modifying agent, to be adsorbed on the oxidized portion of the surface of the upper portion of the recess. The inhibitor layer performs a function to prevent a precursor (a film-forming agent) from being adsorbed on the surface of the wafer 200 in step D to be described below, and to inhibit formation of a film on the surface of the wafer 200. The inhibitor molecule is also called a film formation inhibiting molecule (an adsorption inhibiting molecule, or a reaction inhibiting molecule). The inhibitor layer is also called a film formation inhibiting layer (an adsorption inhibiting layer, or a reaction inhibiting layer).

After the oxidized portion on the surface of the upper portion of the recess is modified, the valve 243c is closed to stop the supply of the modifying agent into the process chamber 201. Then, gaseous substances remaining in the process chamber 201 are removed from the process chamber 201 by the same processing sequence and processing condition as during the purging in step A (purging). The processing temperature during the purging in this step may be the same as the processing temperature during the supply of the modifying agent.

The modifying agent may be, for example, a silicon (Si)-containing gas. That is, the modifying agent may be, for example, a substance in which hydrogen (H) and an amino group are bonded to Si, i.e., an aminosilane-based gas, such as a tetrakis(dimethylamino)silane (Si[N(CH₃)₂]₄) gas, a tris(dimethylamino)silane (Si[N(CH₃)₂]₃H) gas, a bis(diethylamino)silane (Si[N(C₂H₅)₂]₂H₂) gas, a bis(tertiary-butylamino)silane (SiH₂[NH(C₄H₉)]₂) gas, a (diisobutylamino)silane (SiH₃[N(C₄H₉)₂]) gas, a (diisopropylamino)silane (SiH₃[N(C₃H₇)₂]) gas, or the like. Further, the modifying agent may be, for example, a substance in which an amino group and an alkyl group are bonded to Si, i.e., an alkylaminosilane-based gas, such as a (dimethylamino)trimethylsilane ((CH₃)₂NSi(CH₃)₃) gas, a (diethylamino)triethylsilane ((C₂H₅)₂NSi(C₂H₅)₃) (dimethylamino)triethylsilane ((CH₃)₂NSi(C₂H₅)₃) gas, a (diethylamino)trimethylsilane ((C₂H₅)₂NSi(CH₃)₃) gas, a (dipropylamino)trimethylsilane ((C₃H₇)₂NSi(CH₃)₃) gas, or the like. These gases may also be referred to as substances containing at least one selected from the group of H and an alkyl group and an amino group. One or more of these gases may be used as the modifying agent.

A processing condition when the Si-containing gas is supplied as the modifying agent in step C is exemplified as follows:
Processing temperature: room temperature (25 degrees C.) to 500 degrees C., specifically, room temperature to 250 degrees C.,
Processing pressure: 5 to 1,000 Pa,
Processing time: 1 second to 120 minutes, specifically, 30 seconds to 60 minutes, and
Supply flow rate of Si-containing gas: 0.001 to 3 slm, specifically, 0.001 to 0.5 slm.

Further, the modifying agent may be, for example, a fluorine (F)-containing gas. That is, the modifying agent may be, for example, a fluorine (F₂) gas, a nitrogen trifluoride (NF₃) gas, a chlorine trifluoride (ClF₃) gas, a chlorine fluoride (ClF) gas, a hydrogen fluoride (HF) gas, or the like. One or more of these gases may be used as the modifying agent.

A processing condition when the F-containing gas is supplied as the modifying agent in step C is exemplified as follows:
Processing temperature: room temperature (25 degrees C.) to 300 degrees C., specifically, room temperature to 200 degrees C.,

Processing pressure: 1 to 2,000 Pa, specifically, 1 to 1,000 Pa,

Processing time: 1 second to 60 minutes, and

Supply flow rate of F-containing gas: 0.001 to 2 slm, specifically, 0.001 to 0.5 slm

In step C, step C1 of supplying a Si-containing gas as the modifying agent to the wafer 200 and step C2 of supplying a F-containing gas as the modifying agent to the wafer 200 may be performed in the this order. The processing condition in step C1 may be the same as the processing condition when supplying the Si-containing gas described above. The processing condition in step C2 may be the same as the processing condition when supplying the F-containing gas described above. Purging may be performed between steps C1 and C2, and the processing condition in this case may be the same as the processing condition during the purging in step A.

### Step D

After step C is completed, the following steps D1 and D2 are performed to expose the wafer 200 in which the oxidized portion of the upper portion of the recess is modified, i.e., the wafer 200 after the inhibitor layer is selectively formed on the surface of the upper portion of the recess, to a film-forming agent.

### Step D1

In this step, a precursor as a film-forming agent is supplied to the wafer 200.

Specifically, the valve 243e is opened to allow a precursor to flow through the gas supply pipe 232e. A flow rate of the precursor is regulated by the MFC 241e. The precursor is supplied into the process chamber 201 via the gas supply pipe 232b and the nozzle 249b, and is exhausted via the exhaust port 231a. At this time, the precursor is supplied to the wafer 200 from the lateral side of the wafer 200 (supply of precursor). At this time, the valves 243f to 243h may be opened to supply an inert gas into the process chamber 201 via each of the nozzles 249a to 249c.

By supplying the precursor to the wafer 200 under a processing condition to be described below, it is possible to promote selective adsorption of at least a part of a molecular structure of a molecule constituting the precursor on the surface of the portion other than the upper portion of the recess while suppressing at least a part of the molecular structure of the molecule constituting the precursor from being adsorbed on the surface of the upper portion of the recess. As a result, a first layer is formed by causing at least a part of the molecular structure of the molecule constituting the precursor to be selectively (preferentially) adsorbed on the surface of the portion other than the upper portion of the recess.

After the first layer is formed, the valve 243e is closed to stop the supply of the precursor into the process chamber 201. Then, gaseous substances remaining in the process chamber 201 are removed from the process chamber 201 by the same processing sequence and processing condition as during the purging in step A (purging). The processing temperature during the purging in this step may be the same as the processing temperature during the supply of the precursor.

The precursor may be, for example, a substance in which a chloro group (Cl) is bonded to Si, i.e., a chlorosilane-based gas, such as a monochlorosilane (SiH₃Cl) gas, a dichlorosilane (SiH₂Cl₂) gas, a trichlorosilane (SiHCl₃) gas, a tetrachlorosilane (SiCl₄) gas, a hexachlorodisilane (Si₂Cl₆) gas, an octachlorotrisilane (Si₃Cl₈) gas, or the like. Further, the above-described alkylaminosilane-based gas or the above-described aminosilane-based gas may be used as the precursor. One or more of these gases may be used as the precursor.

A processing condition when the precursor is supplied as the film-forming agent in step D1 is exemplified as follows:
Processing temperature: room temperature (25 degrees C.) to 700 degrees C., specifically, 350 to 550 degrees C.,
Processing pressure: 1 to 2,000 Pa, specifically, 1 to 1,333 Pa,
Processing time: 1 to 180 seconds, specifically, 10 to 120 seconds, and
Supply flow rate of precursor: 0.001 to 2 slm, specifically, 0.01 to 1 slm.

### Step D2

In this step, a reactant as a film-forming agent is supplied to the wafer 200. Herein, an example is described in which a nitriding agent (nitriding gas) is used as the reactant.

Specifically, the valve 243d is opened to allow a reactant to flow through the gas supply pipe 232d. A flow rate of the reactant is regulated by the MFC 241d. The reactant is supplied into the process chamber 201 via the gas supply pipe 232a and the nozzle 249a, and is exhausted via the exhaust port 231a. At this time, the reactant is supplied to the wafer 200 from the lateral side of the wafer 200 (Supply of reactant). At this time, the valves 243f to 243h may be opened to supply an inert gas into the process chamber 201 via each of the nozzles 249a to 249c. At this time, the reactant may be plasma-excited and supplied.

By supplying the reactant to the wafer 200 under a processing condition to be described below, it is possible to change (nitride) at least a part of the first layer formed on the surface of the wafer 200 in step D1. As a result, as shown in FIG. 4E, a second layer obtained by nitriding the first layer is selectively (preferentially) formed on the surface of the portion other than the upper portion of the recess.

After the second layer is formed, the valve 243d is closed to stop the supply of the reactant into the process chamber 201. Then, gaseous substances remaining in the process chamber 201 are removed from the process chamber 201 by the same processing sequence and processing condition as during the purging in step A (purging). The processing temperature during the purging in this step may be the same as the processing temperature during the supply of the reactant.

The reactant (nitriding agent) may be, for example, a nitrogen-and hydrogen-containing substance, i.e., a hydrogen nitride-based gas, such as an ammonia (NH₃) gas, a diazene (N₂H₂) gas, a hydrazine (N₂H₄) gas, a N₃H₈ gas, or the like. One or more of these gases may be used as the reactant.

A processing condition when the reactant is supplied as the film-forming agent in step D2 is exemplified as follows:
Processing pressure: 1 to 4,000 Pa, specifically, 1 to 1,333 Pa,
Supply flow rate of reactant: 0.01 to 20 slm, specifically, 0.01 to 10 slm, and
Other processing conditions may be the same as those in step D1.

### Performing Predetermined Number of Times

By performing a sub-cycle including steps D1 and D2 described above a predetermined number of times (m times where m is an integer of 1 or 2 or more), it is possible to promote growth of a film on the surface of the portion other than the upper portion of the recess while suppressing growth of a film on the surface of the upper portion of the recess, and to allow the film to grow conformally in the recess. When the above-described altering agent, oxygen-containing substance, modifying agent, and film-forming agent are used, it is possible to form a film, for example, a silicon nitride film (SiN film), in the recess. The above-described sub-cycle may be performed multiple times. That is, a thickness of the second layer formed per sub-cycle may be made to be smaller than a desired film thickness, and the above-described sub-cycle may be performed multiple times until a thickness of the film formed by stacking the second layer reaches a predetermined thickness.

### After-Purge and Returning to Atmospheric Pressure

After step D is completed, an inert gas as a purge gas is supplied into the process chamber 201 from each of the nozzles 249a to 249c and is exhausted via the exhaust port 231a. Thus, the inside of the process chamber 201 is purged such that gases, reaction by-products, and the like remaining in the process chamber 201 are removed from the inside of the process chamber 201 (after-purge). Thereafter, an internal atmosphere of the process chamber 201 is replaced with an inert gas (replacement of inert gas) and the internal pressure of the process chamber 201 is returned to the atmospheric pressure (returning to atmospheric pressure).

### Boat Unloading and Wafer Discharging

Thereafter, the seal cap 219 is moved down by the boat elevator 115 to open the lower end of the manifold 209. Then, the processed wafers 200 supported by the boat 217 are unloaded from the lower end of the manifold 209 to the outside of the reaction tube 203 (boat unloading). After the boat is unloaded, the shutter 219s is moved and the lower end opening of the manifold 209 is sealed by the shutter 219s via the O-ring 220c (shutter closing). The processed wafers 200 are unloaded from the reaction tube 203 and are then discharged from the boat 217 (wafer discharging).

Steps A to D may be performed in the same process chamber (in-situ). In a case where a series of processes is performed in-situ, the wafer 200 is not exposed to the atmosphere during the processes, and the wafer 200 may be consistently processed while being placed under vacuum. This makes it possible to stably perform the processes.

### (3) Effects of Present Embodiments

According to the present embodiments, one or more of the following effects may be obtained.

(a) By performing the cycle including steps A to D, it is possible to improve the properties of the film formed in the recess. That is, the surface of the upper portion of the recess may be selectively altered and oxidized, and thus the surface of the upper portion of the recess may be selectively modified so as to selectively form an inhibitor layer on the surface of the upper portion of the recess. This makes it possible to promote growth of the film on the surface of the portion other than the upper portion of the recess while suppressing growth of the film on the surface of the upper portion of the recess. That is, it is possible to offset a tendency in the related art that the film is easily grown on the surface of the upper portion of the recess and is difficult to grow on the surface of the portion other than the upper portion of the recess. Thus, it is possible to conformally form the film in the recess. As a result, it is possible to improve a step coverage of the film formed in the recess.

(b) In step A, the surface of the upper portion of the recess is altered. In step B, the altered portion of the surface of the upper portion of the recess is oxidized. In step C, the oxidized portion of the surface of the upper portion of the recess is modified. In step D, a film is grown in the recess while suppressing growth of the film on the surface of the upper portion of the recess. Thus, it is possible to effectively carry out the above-described series of reactions.

(c) In step A, by making the composition of the material constituting the surface of the upper portion of the recess be different from the composition of the material constituting the surface of the portion other than the upper portion of the recess, it is possible to make the oxidation resistance of the surface of the upper portion of the recess be lower than the oxidation resistance of the surface of the portion (the middle portion, the lower portion, and the bottom portion of the recess) other than the upper portion of the recess. Thus, it is possible to effectively carry out the above-described series of reactions.

Further, in step A, by making the composition of the material constituting the surface of the upper portion of the recess be different from the stoichiometric composition, it is possible to make the oxidation resistance of the surface of the upper portion of the recess be lower than the oxidation resistance of the surface of the portion other than the upper portion of the recess. Thus, it is possible to effectively carry out the above-described series of reactions.

For example, when the surface of the recess is constituted by a SiN film, by exposing the substrate to an altering agent excited to a plasma state, i.e., active species such as H₂*, NH₃*, N₂*, and the like in step A, it is possible to generate a Si—H bond, a Si—NH bond, a Si—NH₂ bond, a Si—N—N—Si bond, and the like on the surface of the upper portion of the recess.

Thus, it is possible to make the composition of the material constituting the surface of the upper portion of the recess be different from the composition of the material constituting the surface of the portion other than the upper portion of the recess. For example, it is possible to make H atom concentration (hereinafter, referred to as H concentration) or N atom concentration (hereinafter, referred to as N concentration) in the material constituting the surface of the upper portion of the recess be different from the H concentration or N concentration in the material constituting the surface of the portion other than the upper portion of the recess. Specifically, for example, it is possible to make the H concentration or the N concentration in the material constituting the surface of the upper portion of the recess be higher than the H concentration or the N concentration in the material constituting the surface of the portion other than the upper portion of the recess. Further, it is possible to make the composition of the material constituting the surface of the upper portion of the recess be different from the stoichiometric composition. Specifically, for example, it is possible to make the composition of the material constituting the surface of the upper portion of the recess be a composition in which His excessive (H is rich) with respect to the stoichiometric composition, or a composition in which N is excessive (N is rich) with respect to the stoichiometric composition.

In these cases, the Si—H bond, the Si—NH bond, and the Si—NH₂ bond generated on the surface of the upper portion of the recess may be low in oxidation resistance, and the surface of the upper portion of the recess may be in a state of being liable to oxidize. Further, since the N—N bond in the Si—N—N—Si bond generated on the surface of the upper portion of the recess is unstable, it is possible to make the surface of the upper portion of the recess be in a state of being liable to oxidize. As a result, it is possible to make the oxidation resistance of the surface of the upper portion of the recess be lower than the oxidation resistance of the surface of the portion other than the upper portion of the recess, and it is possible to effectively carry out the above-described series of reactions.

(d) In step A, by breaking the bond between the elements that constitute the material constituting the surface of the upper portion of the recess, it is possible to destabilize the bond between the elements that constitute the material constituting the surface of the upper portion of the recess, and it is possible to make the oxidation resistance of the surface of the upper portion of the recess be lower than the oxidation resistance of the surface of the portion other than the upper portion of the recess. Thus, it is possible to effectively carry out the above-described series of reactions.

For example, when the surface of the recess is constituted by a SiN film, by exposing the substrate to an altering agent excited into a plasma state, i.e., active species such as H₂*, NH₃*, and N₂*, it is possible to break the bond between the elements that constitute the material constituting the surface of the upper portion of the recess, for example, the Si—N bond, and to generate an unstable bond such as a Si—H bond, a Si—NH bond, a Si—NH₂ bond, and a N—N bond on the surface of the upper portion of the recess. That is, the bond between the elements that constitute the material constituting the surface of the upper portion of the recess may be destabilized. This makes it possible to make the oxidation resistance of the surface of the upper portion of the recess be lower than the oxidation resistance of the surface of the portion other than the upper portion of the recess. Thus, it is possible to effectively carry out the above-described series of reactions.

(e) In step A, by making the oxidation resistance of the surface of the upper portion of the recess be lower than the oxidation resistance of the surface of the portion other than the upper portion of the recess, it is possible to make the surface of the upper portion of the recess be more liable to oxidize than the surface of the portion other than the upper portion of the recess. Thus, it is possible to effectively carry out the above-described series of reactions.

(f) In step A, by exposing the substrate to the active species generated by plasma-exciting the altering agent, it is possible to adjust the region to be altered on the surface of the recess with good controllability. Thus, it is possible to adjust the region to be oxidized and the region to be modified on the surface of the recess with good controllability. As a result, it becomes possible to effectively enhance a conformality of the film formed in the recess.

(g) In step A, by controlling the lifetime of the active species generated by plasma-exciting the altering agent, it is possible to adjust the region to be altered on the surface of the recess. This makes it possible to adjust the region to be oxidized and the region to be modified on the surface of the recess with good controllability.

For example, by lengthening the lifetime of the active species generated in step A, the area of the altered portion formed in the recess may be increased, thereby increasing the area in which the oxidized portion is formed in step B and the area in which the inhibitor layer is formed in step C, respectively. As a result, it is possible to perform adjustment to expand a film formation suppression region and reduce a film formation promotion region in the recess. Further, for example, by shortening the lifetime of the active species generated in step A, the area of the altered portion formed in the recess may be reduced, thereby decreasing the area in which the oxidized portion is formed in step B and the area in which the inhibitor layer is formed in step C, respectively. As a result, it is possible to perform adjustment to reduce the film formation suppression region in the recess and expand the film formation promotion region.

By freely changing an area ratio of the film formation suppression region to the film formation promotion region in the recess in accordance with various conditions such as an aspect ratio of the recess, characteristics of the surface in the recess, and a type of film to be formed in the recess as described above, it is possible to effectively enhance the conformality of the film formed in the recess.

(h) The altering agent includes a nitrogen-containing substance, and in step A, by exposing the substrate to the nitrogen-containing active species generated by plasma-exciting the altering agent, it is possible to effectively make the composition of the material constituting the surface of the upper portion of the recess be different from the composition of the material constituting the surface of the portion other than the upper portion of the recess. Further, it is possible to effectively make the composition of the material constituting the surface of the upper portion of the recess be different from the stoichiometric composition. In particular, it is possible to make nitrogen-rich the composition of the material constituting the surface of the upper portion of the recess. As a result, it is possible to make the oxidation resistance of the surface of the upper portion of the recess be lower than the oxidation resistance of the surface of the portion other than the upper portion of the recess, and it is possible to effectively carry out the above-described series of reactions.

(i) The altering agent includes a hydrogen-or deuterium-containing substance, and in step A, the substrate is exposed to hydrogen active species or deuterium active species generated by plasma-exciting the altering agent, thereby making it possible to effectively break the bond between the elements that constitute the material constituting the surface at the upper portion of the recess. This makes it possible to destabilize the bond between the elements that constitute the material constituting the surface of the upper portion of the recess, and to make the oxidation resistance of the surface of the upper portion of the recess be lower than the oxidation resistance of the surface of the portion other than the upper portion of the recess. Thus, it is possible to effectively carry out the above-described series of reactions.

(j) In step B, by making the oxygen concentration in the surface of the upper portion of the recess be different from the oxygen concentration in the surface of the portion other than the upper portion of the recess, it is possible to make the density of the OH termination on the surface of the upper portion of the recess be different from the density of the OH termination on the surface of the portion other than the upper portion of the recess. For example, it is possible to make the oxygen concentration in the surface of the upper portion of the recess be made higher than the oxygen concentration in the surface of the portion other than the upper portion of the recess. In this case, it is possible to make the density of the OH termination on the surface of the upper portion of the recess be higher than the density of the OH termination on the surface of the portion other than the upper portion of the recess. Thus, it is possible to effectively perform the selective modification of the surface of the upper portion of the recess while suppressing the modification of the surface of the portion other than the upper portion of the recess in step C, and it is possible to effectively enhance the conformality of the film formed in the recess in step D.

(k) In step B, by making the density of the OH termination on the surface of the upper portion of the recess be different from the density of the OH termination on the surface of the portion other than the upper portion of the recess, it possible to selectively modify the surface of the upper portion of the recess in step C. For example, it is possible to make the density of the OH termination on the surface of the upper portion of the recess be higher than the density of the OH termination on the surface of the portion other than the upper portion of the recess. Thus, it is possible to effectively perform the selective modification of the surface of the upper portion of the recess while suppressing the modification of the surface of the portion other than the upper portion of the recess in step C, and it is possible to effectively enhance the conformality of the film formed in the recess in step D.

(l) In step B, the substrate after step A is exposed to at least one selected from the group of an oxygen-containing gas, an oxygen-and hydrogen-containing gas, an oxygen-and nitrogen-containing gas, and an oxygen-and carbon-containing gas. Thus, the portion obtained by selectively altering the surface of the upper portion of the recess in step A may be effectively selectively oxidized in step B. In step B, the substrate after step A is exposed to the atmosphere. Therefore, the selective oxidation of the surface of the upper portion of the recess may be effectively and mildly performed. As a result, it is possible to effectively perform the selective modification of the surface of the upper portion of the recess while suppressing the modification of the surface of the portion other than the upper portion of the recess in step C, and it is possible to effectively enhance the conformality of the film formed in the recess in step D.

(m) In step C, the surface of the upper portion of the recess is modified to form an inhibitor layer on the surface of the upper portion of the recess. Thus, in step D, it is possible to effectively promote growth of the film on the surface of the portion other than the upper portion of the recess while suppressing growth of the film on the surface of the upper portion of the recess.

(n) In step C, by using at least one selected from the group of a silicon-containing gas and a fluorine-containing gas as the modifying agent, it is possible to effectively modify the surface of the upper portion of the recess so as to form an inhibitor layer on the surface of the upper portion of the recess. Thus, in step D, it is possible to effectively promote growth of the film on the surface of the portion other than the upper portion of the recess while suppressing growth of the film on the surface of the upper portion of the recess.

(o) In step D, by promoting growth of the film on the surface of the portion other than the upper portion of the recess while suppressing growth of the film on the surface of the upper portion of the recess, it is possible to effectively offset the tendency in the related art that a film is easily grown on the surface of the upper portion of the recess and is difficult to grow on the surface of the portion other than the upper portion of the recess. Thus, it is possible to perform a conformal film formation. As a result, it is possible to effectively improve step coverage of the film formed in the recess. In addition, in step D, the recess may be filled with a film. In this case, the conformal film formation may be performed. Therefore, it is possible to perform a void-free and seamless filling, and to improve filling characteristics.

(p) Since the surface of the recess is constituted by a nitride film, it is possible to effectively carry out the above-described series of reactions.

(q) The above-described effects may be obtained similarly even when a specific substance is arbitrarily selected from the various altering agents, various oxygen-containing substances, various modifying agents, various film-forming agents, and various inert gases described above.

### Other Embodiments of Present Disclosure

The embodiments of the present disclosure are specifically described above. However, the present disclosure is not limited to the above-described embodiments, and various modifications may be made without departing from the spirit of the present disclosure.

For example, as in a processing sequence shown below, after steps A and B are performed, a cycle including steps C and D may be performed a predetermined number of times (n times where n is an integer of 1 or 2 or more). A processing sequence and a processing condition in each step of the present embodiment may be the same as those in each step of the above-described embodiments.

Altering agent→oxygen-containing substance→[modifying agent→(precursor→reactant)×m]×n

The present embodiment also provides the same effects as those of the above-described embodiments. Furthermore, according to the present embodiment, when the inhibitor layer formed on the surface of the substrate is removed and/or invalidated during step D, it is possible to modify the oxidized portion on the surface of the upper portion of the recess again and to restore the inhibitor layer on the surface of the upper portion of the recess. This allows the conformal film formation in the recess to proceed more appropriately.

Further, for example, n in the processing sequence of the above-described embodiments may be set to an integer of 2 or more, and the cycle including steps A to D may be performed two or more times, i.e., multiple times. A processing sequence and a processing condition in each step of the present embodiment may be the same as the processing sequence and processing condition in each step of the above-described embodiments.

The present embodiment also provides the same effects as those of the above-described embodiments. Moreover, according to the present embodiment, when the inhibitor layer formed on the surface of the substrate is removed and/or invalidated during step D, and when the oxidized portion on the surface of the upper portion of the recess is removed (when an OH termination on the surface of the upper portion of the recess is removed), it is possible to restore the removed and/or invalidated portions. That is, it is possible to restore the inhibitor layer on the surface of the upper portion of the recess after the surface of the upper portion of the recess is altered and oxidized again and the OH termination on the surface of the upper portion of the recess is restore. This allows the conformal film formation in the recess to proceed more appropriately.

Further, for example, in step D, in addition to the SiN film, a silicon-containing film such as a silicon film (Si film), a silicon carbonitride film (SiCN film), a silicon boronitride film (SiBN film), a silicon boron carbonitride film (SiBCN film), a silicon boron oxycarbonitride film (SiBOCN film), a silicon oxycarbonitride film (SiOCN film), a silicon oxycarbide film (SiON film), or a silicon oxide film (SiO film) may be formed in the recess. Further, for example, in step D, a conductive metal-containing film such as an aluminum film (Al film), a titanium film (Ti film), a hafnium film (Hf film), a zirconium film (Zr film), a tungsten film (W film), a molybdenum film (Mo film), a ruthenium film (Ru film), or a titanium nitride film (TiN film) may be formed in the recess. Further, for example, an insulating metal-containing film such as an aluminum nitride film (AlN film), an aluminum oxide film (AlO film), a titanium oxide film (TiO film), a hafnium oxide film (HfO film), or a zirconium oxide film (ZrO film) may be formed in the recess in step D. In these embodiments, the same effects as those of the above-described embodiments can be obtained.

Further, for example, the surface of the recess of the substrate, i.e., the base film constituting the surface of the recess, may be constituted by a silicon-containing film such as a Si film, a SiCN film, a SiBN film, a SiBCN film, a SiBOCN film, a SiOCN film, a SiON film, or a SiOC film, in addition to the SiN film. Further, the base film constituting the surface of the recess may be constituted by the metal-containing film described above. In these embodiments, the same effects as those of the above-described embodiments may be obtained.

The Recipes used in the respective processes may be provided individually according to the processing contents and may be recorded and stored in the memory 121c via a telecommunication line or the external memory 123. Moreover, at the beginning of each process, the CPU 121a may properly select an appropriate recipe from a plurality of recipes recorded and stored in the memory 121c according to the processing contents. Thus, it is possible to form films of various types, composition ratios, qualities, and thicknesses with enhanced reproducibility in a processing apparatus. Further, it is possible to reduce an operator's burden and to quickly start each process while avoiding an operation error.

The recipes mentioned above are not limited to newly-provided ones but may be provided, for example, by modifying existing recipes that are already installed in the processing apparatus. Once the recipes are modified, the modified recipes may be installed in the processing apparatus via a telecommunication line or a recording medium storing the recipes. Further, the existing recipes already installed in the processing apparatus may be directly modified by operating the input/output device 122 of the processing apparatus.

An example in which a film is formed by using a batch-type processing apparatus configured to process a plurality of substrates at a time is described in the above-described embodiments of the present disclosure. The present disclosure is not limited to the above-described embodiments of the present disclosure, but may be suitably applied, for example, to a case where a film is formed by using a single-wafer type processing apparatus configured to process a single substrate or several substrates at a time. Further, an example in which a film is formed by using a processing apparatus including a hot-wall-type process furnace is described above in the above-described embodiments. The present disclosure is not limited to the above-described embodiments, but may be suitably applied to a case where a film is formed by using a processing apparatus including a cold-wall-type process furnace.

In the above-described embodiments, the example is described in which the above-described processing sequence is performed in the same process chamber of the same processing apparatus (in-situ). The present disclosure is not limited to the above-described embodiments. For example, any step and any other step of the above-described processing sequence may be performed in different process chambers of different processing apparatuses (ex-situ), or may be performed in different process chambers of the same processing apparatus.

Even when such processing apparatuses are used, each process may be performed by the same processing sequences and processing conditions as those of the above-described embodiments and modifications. The same effects as those of the above-described embodiments and modifications may be obtained.

The above-described embodiments and modifications may be used in combination as appropriate. In such a case, the processing sequence and processing condition may be, for example, the same as the processing sequence and processing condition of the above-described embodiments and modifications.

According to the present disclosure in some embodiments, it is possible to improve properties of a film formed in a recess.

While certain embodiments is described above, these embodiments are presented by way of example, and are not intended to limit the scope of the disclosures. Indeed, the embodiments described herein may be embodied in a variety of other forms. Furthermore, various omissions, substitutions, and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A processing method, comprising:
forming a film in a recess on a surface of a substrate by performing a cycle n times (where n is an integer of 1 or 2 or more), the cycle including:
(a) exposing the substrate to an altering agent excited into a plasma state;
(b) exposing the substrate after (a) to an oxygen-containing substance;
(c) exposing the substrate after (b) to a modifying agent; and
(d) exposing the substrate after (c) to a film-forming agent.

2. The processing method of claim 1, wherein in (a), a surface of an upper portion of the recess is altered,
wherein in (b), an altered portion of the surface of the upper portion of the recess is oxidized,
wherein in (c), an oxidized portion of the surface of the upper portion of the recess is modified, and
wherein in (d), the film is grown in the recess while suppressing growth of the film on the surface of the upper portion of the recess.

3. The processing method of claim 1, wherein in (a), a composition of a material constituting a surface of an upper portion of the recess is made to be different from a composition of a material constituting a surface of a portion other than the upper portion of the recess.

4. The processing method of claim 1, wherein in (a), a composition of a material constituting a surface of an upper portion of the recess is made to be different from a stoichiometric composition of the material.

5. The processing method of claim 1, wherein in (a), a bond between elements that constitute a material constituting a surface of an upper portion of the recess is broken.

6. The processing method of claim 1, wherein in (a), an oxidation resistance of a surface of an upper portion of the recess is made to be lower than an oxidation resistance of a surface of a portion other than the upper portion of the recess.

7. The processing method of claim 1, wherein in (a), the substrate is exposed to active species generated by exciting the altering agent into the plasma state.

8. The processing method of claim 1, wherein in (a), a region of a surface of the recess to be altered is adjusted by controlling a lifetime of active species generated by exciting the altering agent into the plasma state.

9. The processing method of claim 1, wherein the altering agent includes a nitrogen-containing substance, and
wherein in (a), the substrate is exposed to nitrogen-containing active species generated by exciting the altering agent into the plasma state.

10. The processing method of claim 1, wherein the altering agent includes a hydrogen- or deuterium-containing substance, and
wherein in (a), the substrate is exposed to hydrogen active species or deuterium active species generated by exciting the altering agent into the plasma state.

11. The processing method of claim 1, wherein in (b), an oxygen concentration in a surface of an upper portion of the recess is made to be different from an oxygen concentration in a surface of a portion other than the upper portion of the recess.

12. The processing method of claim 1, wherein in (b), a density of an OH termination on a surface of an upper portion of the recess is made to be different from a density of an OH termination on a surface of a portion other than the upper portion of the recess.

13. The processing method of claim 1, wherein in (b), the substrate after (a) is exposed to at least one selected from the group of an oxygen-containing gas, an oxygen- and hydrogen-containing gas, an oxygen- and nitrogen-containing gas, and an oxygen-and carbon-containing gas.

14. The processing method of claim 1, wherein in (b), the substrate after (a) is exposed to an atmosphere.

15. The processing method of claim 1, wherein in (c), a surface of an upper portion of the recess is modified to form an inhibitor layer on the surface of the upper portion of the recess.

16. The processing method of claim 1, wherein in (c), at least one selected from the group of a silicon-containing gas and a fluorine-containing gas is used as the modifying agent.

17. The processing method of claim 1, wherein in (d), growth of the film on a surface of a portion other than an upper portion of the recess is promoted while suppressing growth of the film on a surface of the upper portion of the recess.

18. The processing method of claim 1, wherein a surface of the recess is constituted by a nitride film.

19. A method of manufacturing a semiconductor device, comprising the processing method of claim 1.

20. A processing apparatus, comprising:
a first exposure system configured to expose a substrate to an altering agent excited into a plasma state;
a second exposure system configured to expose the substrate to an oxygen-containing substance;
a third exposure system configured to expose the substrate to a modifying agent;
a fourth exposure system configured to expose the substrate to a film-forming agent; and
a controller configured to be capable of controlling the first exposure system, the second exposure system, the third exposure system, and the fourth exposure system so as to perform a process comprising:
forming a film in a recess on a surface of the substrate by performing a cycle n times (where n is an integer of 1 or 2 or more), the cycle including:
(a) exposing the substrate to the altering agent excited into the plasma state;
(b) exposing the substrate after (a) to the oxygen-containing substance;
(c) exposing the substrate after (b) to the modifying agent; and
(d) exposing the substrate after (c) to the film-forming agent.

21. A non-transitory computer-readable recording medium storing a program that causes, by a computer, a processing apparatus to perform a process comprising:
forming a film in a recess on a surface of a substrate by performing a cycle n times (where n is an integer of 1 or 2 or more), the cycle including:
(a) exposing the substrate to an altering agent excited into a plasma state;
(b) exposing the substrate after (a) to an oxygen-containing substance;
(c) exposing the substrate after (b) to a modifying agent; and
(d) exposing the substrate after (c) to a film-forming agent.
